(19) United States
(12) Patent Application Publication
(10) Pub. No.: US 2014/0353627 A1
(43) Pub. Date: Dec. 4, 2014

(54) DISPLAY DEVICE AND METHOD OF MANUFACTURING THE SAME

(71) Applicant: Samsung Display Co., Ltd., Yongin-city (KR)

(72) Inventor: Seung-Kyu Park, Yongin-city (KR)

(73) Assignee: Samsung Display Co., Ltd., Yongin-city (KR)

(21) Appl. No.: 14/173,349

(22) Filed: Feb. 5, 2014

(30) Foreign Application Priority Data
Jun. 4, 2013 (KR) 10-2013-0063955

(51) Int. Cl. H01L 51/52; H01L 51/56; H01L 27/32

(52) U.S. Cl. CPC H01L 51/5221; H01L 27/3248; H01L 51/56
USPC 257/40; 438/34

(57) ABSTRACT

A display device includes a first substrate, an anode electrode, a pixel defining layer, an organic light emitting layer, a multi-layered complex, a passivation insulating layer and a second substrate. The anode electrode is disposed on the first substrate. The pixel defining layer is disposed on the first substrate and defines a display region and a peripheral region thereon. The organic light emitting layer is disposed on and covers the anode electrode and the pixel defining layer, and is configured to generate light. The multi-layered complex is disposed on and covers the organic light emitting layer, and is configured to apply a current to the organic light emitting layer. The multi-layered complex includes a plurality of conducting layers laminated to each other. The passivation insulating layer is disposed on and covers the multi-layered complex. The second substrate is disposed on the passivation insulating layer and corresponds to the first substrate.

### CROSS-REFERENCE TO RELATED APPLICATIONS

This application claims priority to Korean Patent Application No. 10-2013-0063955 filed on Jun. 4, 2013, the disclosure of which is hereby incorporated by reference herein in its entirety.

### BACKGROUND

1. Field

Example embodiments relate to a display device having a multi-layered complex and a method of manufacturing the same.

2. Description of the Related Technology

Generally, a display device has an organic light emitting element and a thin film transistor that drives the organic light emitting element. In addition, the display device is manufactured to have a laminated structure. Accordingly, in the manufacturing process, a particle may enter into a display device, so that the elements of the display device may be short-circuited. The short-circuited elements may generate a dark pixel in the display device. As a result, the dark pixel may degrade definition of the display device.

### SUMMARY OF CERTAIN INVENTIVE ASPECTS

Example embodiments provide a display device having a multi-layered complex without a dark pixel caused by a particle.

Example embodiments provide a method of manufacturing the above-mentioned display device.

According to one aspect of example embodiments, a display device includes a first substrate, an anode electrode, a pixel defining layer, an organic light emitting layer, a multi-layered complex, a passivation insulating layer and a second substrate. The first substrate includes a display region and a peripheral region. The peripheral region surrounds the display region. The anode electrode is disposed on the first substrate. The pixel defining layer is disposed on the first substrate. The pixel defining layer defines the display region and the peripheral region. The organic light emitting layer is disposed on and covers the anode electrode and the pixel defining layer. The organic light emitting layer is configured to generate a light. The multi-layered complex is disposed on and covers the organic light emitting layer. The multi-layered complex is configured to apply a current to the organic light emitting layer. The multi-layered complex includes a plurality of conducting layers laminated to each other. The passivation insulating layer is disposed on and covers the multi-layered complex. The second substrate is disposed on and covers the passivation insulating layer. The second substrate corresponds to the first substrate.

The multi-layered complex may include a first cathode electrode, a buffer layer and a second cathode electrode.

The first cathode electrode may be disposed on and cover the organic light emitting layer.

The second cathode electrode may be disposed on and cover the buffer layer.

The buffer layer may be disposed in the display region of between the first cathode electrode and the second cathode electrode.

A thickness of the first cathode electrode may be smaller than a thickness of the second cathode electrode.

The second cathode electrode may be electrically connected with the first cathode electrode in the peripheral region.

The display device may further include a particle, and the particle is disposed in between the anode electrode and the organic light emitting layer.

The multi-layered complex may be configured to cover the particle.

According to another aspect of example embodiments, a method of manufacturing a display device is provided as follows. An anode electrode is formed on a first substrate. A pixel defining layer is formed on the first substrate. The pixel defining layer defines a display region and a peripheral region. An organic light emitting layer formed on the anode electrode and the pixel defining layer. A first cathode electrode is formed on the organic light emitting layer. A buffer layer is formed in the display region on the first cathode electrode. A second cathode electrode is formed on the buffer layer. A passivation insulating layer is formed on the second cathode electrode. A second substrate is formed on the passivation insulating layer.

A thickness of the first cathode electrode may be smaller than a thickness of the second cathode electrode.

The second cathode electrode may be disposed on the buffer layer, and the second cathode electrode may be electrically connected with the first cathode electrode in peripheral region.

The buffer layer may be disposed between the first cathode electrode and the second cathode electrode, and the buffer layer may be formed in the display region using a pattern mask.

The method of manufacturing a display device may further include a particle, and the particle may be disposed between the anode electrode and the organic light emitting layer.

The multi-layered complex may be configured to cover the particle.

According to the display device and the method of manufacturing a display device, the display device having the multi-layered complex may prevent the short-circuit phenomenon which is generated by contact of an anode and a cathode.

### BRIEF DESCRIPTION OF THE DRAWINGS

Example embodiments can be understood in more detail from the following description taken in conjunction with the accompanying drawings, in which:

FIG. 1 is a cross-sectional view illustrating a display device according to the prior art;

FIG. 2 is a cross-sectional view illustrating a display device in accordance with another example embodiment of the present invention;

FIG. 3 is a cross-sectional view illustrating the display device of FIG. 2 having a particle;

FIG. 4 is a graph illustrating the number of dark pixels in accordance with thickness of a cathode electrode of the display device of FIG. 2; and

FIG. 5 is a flow chart illustrating the method of manufacturing the display device of FIG. 2.

### DETAILED DESCRIPTION OF CERTAIN INVENTIVE EMBODIMENTS

Some example embodiments are described more fully hereinafter with reference to the accompanying drawings. The inventive concept may, however, be embodied in many different forms and should not be construed as limited to the example embodiments set forth herein. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer, or intervening elements or layers may be present. In contrast, when an element is referred to as being “directly on,” “directly connected to” or “directly coupled to” another element or layer, there are no intervening elements or layers present. Like or similar reference numerals generally refer to like or similar elements throughout. As used herein, the term “and/or” includes any and all combinations of one or more of the associated listed items.

It will be understood that, although the terms first, second, third etc. may be used herein to describe various elements, components, regions, layers, patterns and/or sections, these elements, components, regions, layers, patterns and/or sections should not be limited by these terms. These terms are only used to distinguish one element, component, region, layer pattern or section from another region, layer, pattern or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the apparatus in use or operation in addition to the orientation depicted in the figures. For example, if the apparatus in the figures is turned over, elements described as “below” or “beneath” other elements or features would then be oriented “above” the other elements or features. Thus, the example term “below” can encompass both an orientation of above and below. The apparatus may be otherwise oriented (for example, rotated 90 degrees or at other orientations) and the spatially relative descriptors used herein interpreted accordingly.

The terminology used herein is for the purpose of describing particular example embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross sectional illustrations that are schematic illustrations of illustratively idealized example embodiments (and intermediate structures) of the inventive concept. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. The regions illustrated in the figures are schematic in nature and their shapes are not intended to illustrate the actual shape of a region of an apparatus and are not intended to limit the scope of the inventive concept.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

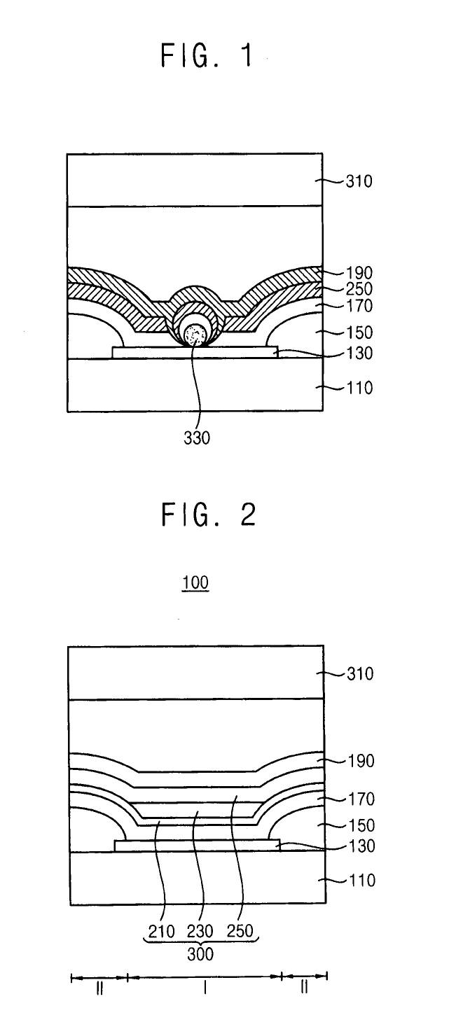

FIG. 1 is a cross-sectional view illustrating a display device according to the prior art.

Referring to FIG. 1, when a particle 330 is disposed on an anode electrode 130, an organic light emitting layer 170 may be short-circuited. Also, the organic light emitting layer 170 may not be evenly formed on the anode electrode 130, and the organic light emitting layer 170 may surround the particle 330. In addition, a cathode electrode 250 is formed on the organic light emitting layer 170, and the cathode electrode 250 may be short-circuited. Furthermore, the cathode electrode 250 may not be evenly formed on the organic light emitting layer 170, and the cathode electrode 250 may surround the organic light emitting layer 170. Thus, the cathode electrode 250 may be contacted with the anode electrode 130. Therefore, the short-circuit may be generated between the anode electrode 130 and the cathode electrode 250.

FIG. 2 is a cross-sectional view illustrating a display device in accordance with one example embodiment of the present invention.

Referring to FIG. 2, a display device 100 includes a first substrate 110, an anode electrode 130, a pixel defining layer 150, an organic light emitting layer 170, a multi-layered complex 300, a passivation insulating layer 190 and a second substrate 310.

The first substrate 110 may include a transparent insulating substrate. For example, the first substrate 110 may include a glass substrate, a quartz substrate, a polymer resin substrate, or the like. In one embodiment, the first substrate 110 may include a thin film transistor glass (TFT glass).

The second substrate 310 may correspond to the first substrate 110. The second substrate 310 may include transparent insulating materials. The second substrate 310 may include a glass substrate, a quartz substrate, a polymer resin substrate, or the like. In one embodiment, the second substrate 310 may include an encapsulation glass.

Referring again to FIG. 2, the first substrate 110 may include a display region I and a peripheral region II.

The anode electrode 130 is disposed in the display region I of the first substrate 110. The anode electrode 130 may include transparent conductive materials such as transparent conductive oxide (TCO), indium tin oxide (ITO), indium zinc oxide (IZO), and the like. When the anode electrode 130 is formed as a transparent conductive electrode, a light is generated from the organic light emitting layer 170 through the anode electrode 130, so that the display device 100 is a bottom emission type.

The pixel defining layer 150 is disposed in both side portions of the first substrate 110, and the pixel defining layer 150 partially exposes the anode electrode 130. The pixel defining layer 150 may be formed by using organic materials or inorganic materials. For example, the pixel defining layer 150 may be formed by using photoresist, polyacrylic resin, polyimide resin, acrylic resin, SiOx or the like. An exposed portion of the anode electrode 130 by the pixel defining layer 150 can define the display region I of the display device 100 and other potions can define the peripheral region II of the display device 100.

The organic light emitting layer 170 is disposed on the anode electrode 130 and the pixel defining layer 150, and the organic light emitting layer 170 may cover the anode electrode 130 and the pixel defining layer 150. The organic light emitting layer 170 may include a hole injection layer (HIL) a hole transport layer (HTL), an emitting layer (EL), an electron transport layer (ETL) and an electron injection layer (EIL). The organic light emitting layer 170 generates a light using a driving signal from a driving circuit (not shown). In the display region I of the display device 100, an image is displayed by the light generated in the organic light emitting layer 170.

The display region I is disposed in the center of the first substrate 110, and the peripheral region II is disposed in both side portions of the first substrate 110, and the peripheral region II surrounds the display region I.

The multi-layered complex 300 is disposed on the organic light emitting layer 170, and the multi-layered complex 300 covers the organic light emitting layer 170.

In one embodiment, the multi-layered complex 300 may include a first cathode electrode 210, a buffer layer 230 and a second cathode electrode 250.

The first cathode electrode 210 is disposed on the organic light emitting layer 170, and the first cathode electrode 210 covers the organic light emitting layer 170. The first cathode electrode 210 may be formed with metal materials such as, for example, aluminum (Al). In one embodiment, in case of display device 100 being a bottom emission type, the light which is generated by the organic light emitting layer 170 may pass through the first cathode electrode 210. Thus, thickness of the first cathode electrode 210 may be formed below about 1000 Å.

When the thickness of the first cathode electrode 210 and the second cathode electrode 250 are thicker, the transmittance of the light is decreased and the conductivity of the cathode electrodes is increased. On the other hand, when the thickness of the first cathode electrode 210 and the second cathode electrode 250 are thinner, the transmittance of the light is increased and the conductivity of the cathode electrodes is decreased. Accordingly, because the transmittance and the conductivity are inversely proportional, an appropriate thickness of the first cathode electrode 210 and the second cathode electrode 250 is determined. The thickness of the first cathode electrode 210 and the second cathode electrode 250 are interdependent.

The buffer layer 230 is disposed on the first cathode electrode 210. The buffer layer 230 partially covers the first cathode electrode 210, and the buffer layer 230 is disposed on the display region I of the first cathode electrode 210. In one embodiment, the buffer layer 230 may include a capping layer. In addition, the buffer layer 230 is formed by using silicon nitride, silicon oxide, an inorganic layer such as metal oxide or the like, or an organic layer such as acrylate or the like. For example, the buffer layer 230 may be formed on the first cathode electrode 210 using a spin-coating process, a chemical vapor deposition (CVD) process, a plasma enhanced chemical vapor deposition (PECVD) process, a high-density plasma-chemical vapor deposition (HDP-CVD) process, a printing process or the like. In other embodiments, the buffer layer 230 may be formed on the first cathode electrode 210 with a stripe or a mesh type using a fine metal mask (FMM) process.

The second cathode electrode 250 is disposed on the buffer layer 230 and the substrate 110, and partially covers the buffer layer 230 and the first cathode electrode 210. The second cathode electrode 250 may be formed with a metal material such as, for example, aluminum (Al). In one embodiment, in case of the display device 100 being of a bottom emission type, the second cathode electrode 250 may be formed by using highly reflective metals, alloys with reflective or the like. In addition, the buffer layer 230 is formed between the first cathode electrode 210 and the second cathode electrode 250, in the display region I, and then the first cathode electrode 210 and the second cathode electrode 250 do not contact one another. But, in the peripheral region II, the first cathode electrode 210 and the second cathode electrode 250 may be electrically contacted with each other. Thus, without increase of resistance of the entire panel, a charge can move.

The passivation insulating layer 190 is disposed on the multi-layered complex 300, and the passivation insulating layer 190 covers the multi-layered complex 300. The passivation insulating layer 190 may be formed by using silicon nitride (SiNx), silicon oxide (SiOx), or the like.

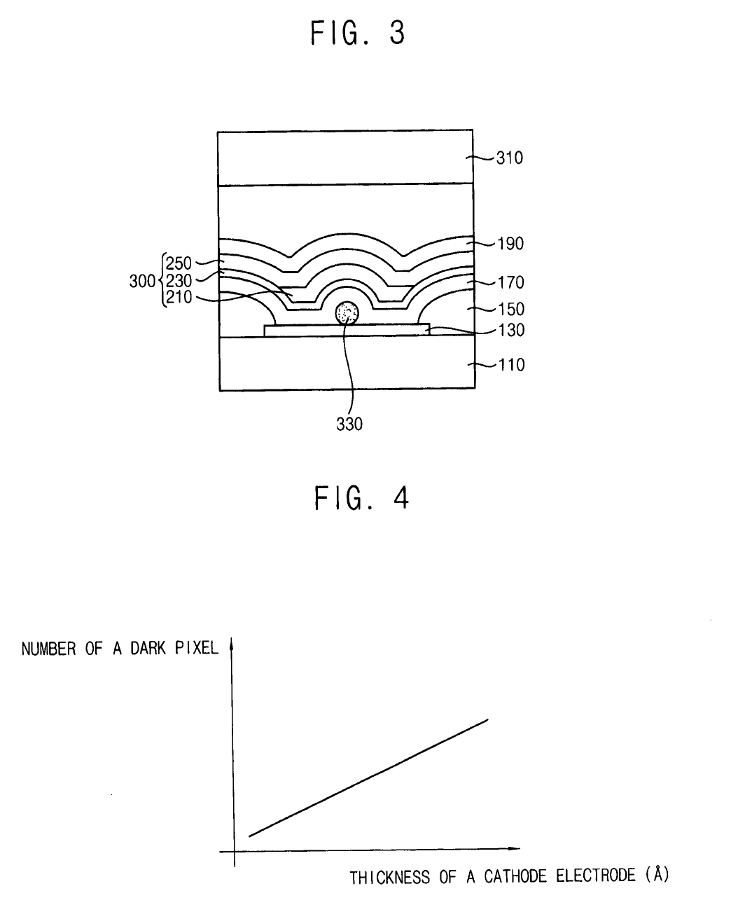

FIG. 3 is a cross-sectional view illustrating the display device of FIG. 2 having a particle.

Referring to FIG. 3, the display device 100 includes a first substrate 110, an anode electrode 130, a pixel defining layer 150, a particle 330, an organic light emitting layer 170, a multi-layered complex 300, a passivation insulating layer 190 and a second substrate 310.

The first substrate 110 may include a transparent insulating substrate. For example, the first substrate 110 may include a glass substrate, a quartz substrate, a polymer resin substrate, or the like. In one embodiment, the first substrate 110 may include a thin film transistor glass (TFT glass).

The second substrate 310 may correspond to the first substrate 110. The second substrate 310 may include transparent insulating materials. The second substrate 310 may include a glass substrate, a quartz substrate, a polymer resin substrate, or the like. In one embodiment, the second substrate 310 may include an encapsulation glass.

Referring still to FIG. 3, the first substrate 110 may include a display region I and a peripheral region II.

The anode electrode 130 is disposed in the display region I of the first substrate 110. The anode electrode 130 may include transparent conductive materials such as transparent conductive oxide (TCO), indium tin oxide (ITO) indium zinc oxide (IZO), or the like. When the anode electrode 130 is formed as transparent conductive electrodes, a light which is generated from the organic light emitting layer 170 through the anode electrode 130, so that the display device 100 is a bottom emission type.

The pixel defining layer 150 is disposed in both side portions of the first substrate 110, and the pixel defining layer 150 partially exposes the anode electrode 130. The pixel defining layer 150 may be formed by using organic materials or inorganic materials. For example, the pixel defining layer 150 may be formed by using photoresist, polyacrylic resin, polyimide resin, acrylic resin, SiOx or the like. An exposed portion of the anode electrode 130 by the pixel defining layer 150 can define the display region I of the display device 100 and other potions can define the peripheral region II of the display device 100.

The particle 330 is disposed on the anode electrode 130. The particle 330 may include debris generated in a process to remove the thin film transistor, in a process to move the substrate, or in an organic light emitting device vacuum chamber, or the like. In the prior art, when the particle 330 is disposed on the anode electrode 130, and the organic light emitting layer 170 is disposed on the particle 330, and the organic light emitting layer 170 may not be evenly formed. As a result, a dark pixel may be generated in the display device 100 (referring to FIG. 1).

The organic light emitting layer 170 is disposed on the anode electrode 130 and the pixel defining layer 150, and the organic light emitting layer 170 may cover the anode electrode 130 and the pixel defining layer 150. In this case, when the particle 330 is disposed on the anode electrode 130, the organic light emitting layer 170 surrounds the particle 330, and the organic light emitting layer 170 may be evenly formed. Thus, the organic light emitting layer 170 does not generate short-circuit-circuit phenomenon by the particle 330. The organic light emitting layer 170 may include a hole injection layer (HIL) a hole transport layer (HTL), an emitting layer (EL), an electron transport layer (ETL) and an electron injection layer (EIL). The organic light emitting layer 170 generates a light using a driving signal from a driving circuit. In the display region I of the display device 100, an image is displayed by the light generated in the organic light emitting layer 170.

The display region I is disposed in the center of the first substrate 110, and the peripheral region II is disposed in both side portions of the first substrate 110, and the peripheral region II surrounds the display region I.

The multi-layered complex 300 is disposed on the organic light emitting layer 170, and the multi-layered complex 300 covers the organic light emitting layer 170.

In one embodiment, the multi-layered complex 300 may include a first cathode electrode 210, a buffer layer 230 and a second cathode electrode 250.

The first cathode electrode 210 is disposed on the organic light emitting layer 170, and the first cathode electrode 210 covers the organic light emitting layer 170. At this point, if the particle 330 is disposed on the anode electrode 130, the organic light emitting layer 170 surrounds the particle 330, and then the organic light emitting layer 170 is disposed on the particle 330 without the short-circuit phenomenon. In addition, the first cathode electrode 210 surrounds the organic light emitting layer 170, and the first cathode electrode 210 may be evenly formed on the organic light emitting layer 170 without the short-circuit phenomenon. As a result, the first cathode electrode 210 does not generate the short-circuit phenomenon by the particle 330. The first cathode electrode 210 may be formed of metal materials such as, for example, aluminum (Al).

In one embodiment, in case of display device 100 being of a bottom emission type, the light which is generated by the organic light emitting layer 170 may pass through the first cathode electrode 210. Thus, thickness of the first cathode electrode 210 may be formed to be below about 1000 Å.

When the thickness of the first cathode electrode 210 and the second cathode electrode 250 are thicker, the transmittance of the light is decreased and the conductivity of the cathode electrodes is increased. On the other hand, when the thickness of the first cathode electrode 210 and the second cathode electrode 250 are thinner, the transmittance of the light is increased and the conductivity of the cathode electrodes is decreased. Accordingly, because the transmittance and the conductivity are inversely proportional, the appropriate thickness of the first cathode electrode 210 and the second cathode electrode 250 are determined. The thicknesses of the first cathode electrode 210 and the second cathode electrode 250 are interdependent.

The buffer layer 230 is disposed on the first cathode electrode 210. The buffer layer 230 partially covers the first cathode electrode 210, and the buffer layer 230 is disposed on the display region I of the first cathode electrode 210. If the particle 330 is disposed on the anode electrode 130, the organic light emitting layer 170 surrounds the particle 330, and then the organic light emitting layer 170 is disposed on the particle 330 without the short-circuit phenomenon. In addition, the first cathode electrode 210 surrounds the organic light emitting layer 170, and then the first cathode electrode 210 may be evenly formed on the organic light emitting layer 170 without the short-circuit phenomenon, and the buffer layer 230 surrounds the first cathode electrode 210, and then the buffer layer 230 may be evenly formed on the first cathode electrode 210 without the short-circuit phenomenon.

As a result, the buffer layer 230 does not generate the short-circuit phenomenon by the particle 330. In one embodiment, the buffer layer 230 may include a capping layer. In addition, the buffer layer 230 is formed by using silicon nitride, silicon oxide, an inorganic layer such as metal oxide or the like, or an organic layer such as acrylate or the like. For example, the buffer layer 230 may be formed on the first cathode electrode 210 using a spin-coating process, a chemical vapor deposition (CVD) process, a plasma enhanced chemical vapor deposition (PECVD) process, a high-density plasma-chemical vapor deposition (HDP-CVD) process, a printing process or the like. In other embodiments, the buffer layer 230 may be formed on the first cathode electrode 210 with a stripe or a mesh type using a fine metal mask (FMM) process.

The second cathode electrode 250 is disposed on the buffer layer 230, and the substrate 110 partially covers the buffer layer 230 and the first cathode electrode 210. If the particle 330 is disposed on the anode electrode 130, the organic light emitting layer 170 surrounds the particle 330, and then the organic light emitting layer 170 is disposed on the particle 330 without the short-circuit phenomenon. In addition, the first cathode electrode 210 surrounds the organic light emitting layer 170, and then the first cathode electrode 210 may be evenly formed on the organic light emitting layer 170 without the short-circuit phenomenon. The buffer layer 230 surrounds the first cathode electrode 210, and then the buffer layer 230 may be evenly formed on the first cathode electrode 210 without the short-circuit phenomenon. The second cathode electrode 250 surrounds the portion of the first cathode electrode 210 and the buffer layer 230, and then the second cathode electrode 250 may evenly formed on the portion of the first cathode electrode 210 and the buffer layer 230 without the short-circuit phenomenon. As a result, the second cathode electrode 250 does not generate the short-circuit phenomenon by the particle 330.

The second cathode electrode 250 may be formed with metal material such as, for example, aluminum (Al). In one embodiment, in case of the display device 100 being a bottom emission type structure, the second cathode electrode 250 may be formed by using highly reflective metals, alloys with reflective or the like. In addition, the buffer layer 230 is formed between the first cathode electrode 210 and the second cathode electrode 250, in the display region I, and then the first cathode electrode 210 and the second cathode electrode 250 are not in contact with one another. But, in the peripheral region II, the first cathode electrode 210 and the second cathode electrode 250 may be in electrically contact with one another. Thus, without increase of resistance of the entire panel, a charge can move.

The passivation insulating layer 190 is disposed on the multi-layered complex 300, and the passivation insulating layer 190 covers the multi-layered complex 300. If the particle 330 is formed on the anode electrode 130, the passivation insulating layer 190 can include the curve along the top of the particle 330, the passivation insulating layer 190 may evenly formed on the multi-layered complex 300 without the short-circuit phenomenon. The passivation insulating layer 190 may be formed by using silicon nitride (SiNx), silicon oxide (SiOx), or the like.

Accordingly, as the display device 100 has the multi-layered complex 300, when the particle 330 is disposed on the anode electrode 130, it can avoid contact of the anode electrode 130 and second cathode electrode 250, and the short-circuit phenomenon between the anode electrode 130 and second cathode electrode 250 can be prevented. As a result, the multi-layered complex 300 can prevent a dark pixel from occurring.

FIG. 4 is a graph illustrating the number of dark pixels in accordance with thickness of a cathode electrode of display device of FIG. 2.

Referring to FIG. 4, experimentally, when the thickness of a cathode is about 3000 Å, the number of dark pixels which is generated in the display device 100 is around 56, and when the thickness of a cathode is about 700 Å, the number of dark pixels which is generated in the display device 100 is around 6. Accordingly, when the thickness of the cathode is thinner, the number of dark pixels is decreased, and it has been demonstrated experimentally. As a result, in case of a manufacture of the display device 100, it is desirable to form the cathode with a small thickness.

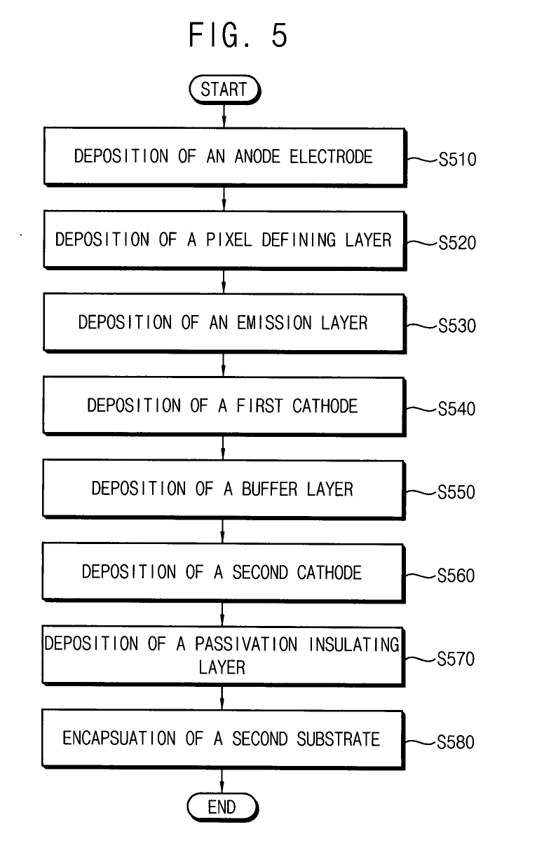

FIG. 5 is a flow chart illustrating a method of manufacturing the display device of FIG. 2.

Referring to FIG. 5, the anode electrode 130 is disposed in the display device 100 of the first substrate 110 (Step S510). In one embodiment, the anode electrode 130 may be formed with transparent conductive materials. A particle 330 may be disposed on the anode electrode 130.

The pixel defining layer 150 is disposed in order to expose the portion of the anode electrode 130 which is disposed in both side portions the first cathode electrode 210 (Step S520).

The organic light emitting layer 170 is disposed on the anode electrode 130 and the pixel defining layer 150, and the organic light emitting layer 170 may cover the anode electrode 130 and the pixel defining layer 150 (Step S530). In one embodiment, the particle 330 is disposed between the anode electrode 130 and the organic light emitting layer 170.

The first cathode electrode 210 is disposed on the organic light emitting layer 170(Step S540). In another embodiment, the first cathode electrode 210 may be formed thinly.

The buffer layer 230 is disposed on the first cathode electrode 210 (Step S550). In one embodiment, the buffer layer 230 may include a capping layer.

The second cathode electrode 250 is disposed on the buffer layer 230 (Step S560). In one embodiment, in case of the display device 100 being a bottom emission type structure, the second cathode electrode 250 may be formed by using highly reflective metals, alloys with reflective or the like.

The passivation insulating layer 190 is disposed on the second cathode electrode 250 (Step S570). In one embodiment, the passivation insulating layer 190 may be formed with silicon nitride (SiNx), silicon oxide (SiOx) or the like.

The second substrate 310 is encapsulated on the passivation insulating layer 190 (Step S580).

Embodiments of the present invention may be applied to any system having a display apparatus using an organic light emitting element. For example, the present may be applied to a notebook, a cellular, a smart phone, a PDA, a navigation device, a GPS device, or the like.

The foregoing is illustrative of example embodiments, and is not to be construed as limiting thereof. Although a few example embodiments have been described, those skilled in the art will readily appreciate that many modifications are possible in the example embodiments without materially departing from the novel teachings and advantages of example embodiments. Accordingly, all such modifications are intended to be included within the scope of example embodiments as defined in the claims. In the claims, means-plus-function clauses are intended to cover the structures described herein as performing the recited function and not only structural equivalents but also equivalent structures. Therefore, it is to be understood that the foregoing is illustrative of example embodiments and is not to be construed as limited to the specific embodiments disclosed, and that modifications to the disclosed example embodiments, as well as other example embodiments, are intended to be included within the scope of the appended claims. The inventive concept is defined by the following claims, with equivalents of the claims to be included therein.

What is claimed is:

1. A display device, comprising:
a first substrate including a display region and a peripheral region, the peripheral region surrounding the display region;
an anode electrode disposed on the first substrate;
a pixel defining layer disposed on the first substrate, the pixel defining layer defining the display region and the peripheral region;
an organic light emitting layer disposed on and covering the anode electrode and the pixel defining layer, the organic light emitting layer configured to generate a light;
a multi-layered complex disposed on and covering the organic light emitting layer, the multi-layered complex configured to apply a current to the organic light emitting layer, the multi-layered complex including a plurality of conducting layers laminated to each other;
a passivation insulating layer disposed on and covering the multi-layered complex; and
a second substrate disposed on the passivation insulating layer, the second substrate corresponding to the first substrate.

2. The display device of claim 1, wherein the multi-layered complex comprises a first cathode electrode, a buffer layer and a second cathode electrode.

3. The display device of claim 2, wherein the first cathode electrode is disposed on and covers the organic light emitting layer.

4. The display device of claim 2, wherein the second cathode electrode is disposed on and covers the buffer layer.

5. The display device of claim 2, wherein the buffer layer is disposed in the display region between the first cathode electrode and the second cathode electrode.

6. The display device of claim 2, wherein a thickness of the first cathode electrode is smaller than a thickness of the second cathode electrode.

7. The display device of claim 2, wherein the second cathode electrode is electrically connected to the first cathode electrode in the peripheral region.

8. The display device of claim 1, wherein the display device further comprises a particle, and the particle is disposed between the anode electrode and the organic light emitting layer.

9. The display device of claim 8, wherein the multi-layered complex is configured to cover the particle.

10. A method of manufacturing a display device, the method comprising:
forming an anode electrode on a first substrate;
forming a pixel defining layer on the first substrate, the pixel defining layer defining a display region and a peripheral region;
forming an organic light emitting layer on the anode electrode and the pixel defining layer;
forming a first cathode electrode on the organic light emitting layer;
forming a buffer layer in the display region on the first cathode electrode;
forming a second cathode electrode on the buffer layer;
forming a passivation insulating layer on the second cathode electrode;
forming a second substrate on the passivation insulating layer.

11. The method of claim 10, wherein a thickness of the first cathode electrode is smaller than a thickness of the second cathode electrode.

12. The method of claim 10, wherein the second cathode electrode is disposed on the buffer layer, and the second cathode electrode is electrically connected to the first cathode electrode in peripheral region.

13. The method of claim 10, wherein the buffer layer is disposed between the first cathode electrode and the second cathode electrode, and the buffer layer is formed in the display region using a pattern mask.

14. The method of claim 10, further comprising a particle, wherein the particle is disposed between the anode electrode and the organic light emitting layer.

15. The method of claim 14, wherein the multi-layered complex is configured to cover the particle.
